(19) United States
(12) Patent Application Publication
(10) Pub. No.: US 2025/0257444 A1
(43) Pub. Date: Aug. 14, 2025

(54) Co-Cr-Pt-OXIDE-BASED SPUTTERING TARGET

(71) Applicant: TANAKA PRECIOUS METAL TECHNOLOGIES, LTD., Tokyo (JP)

(72) Inventors: Yasuyuki Goto, Singapore (SG); Toyokazu Eguchi, Ibaraki (JP); Yasunobu Watanabe, Ibaraki (JP); Jun Tadokoro, Ibaraki (JP)

(21) Appl. No.: 18/992,526

(22) PCT Filed: Jun. 1, 2023
(86) PCT No.: PCT/JP2023/020398

§ 371 Date: Jan. 8, 2025

(30) Foreign Application Priority Data
Jul. 12, 2022 (JP) 2022-111636

(51) Int. Cl. C23C 14/34; C22C 1/04; C22C 19/07

(52) U.S. Cl. CPC C23C 14/34; C22C 1/0433; C22C 19/07

(57) ABSTRACT

A Co—Cr—Pt-oxide-based sputtering target containing 50 at % or more of Co, more than 0 at % and 20 at % or less of Cr, and more than 0 at % and 25 at % or less of Pt, with the balance being one or more oxides and incidental impurities, wherein the sputtering target contains (A) a composite phase in which Co, Pt, and one or more oxides are mutually dispersed and (B) a metal Cr phase; and wherein the sputtering target comprises 10 or more metal Cr phases having an equivalent circle diameter of greater than 10 μm and 100 μm or less in a 1 mm×1 mm field of view under a SEM at a magnification of 50×.

### TECHNICAL FIELD

The present invention relates to a sputtering target suitable for forming a magnetic thin film, in particular, a granular film used as a magnetic recording layer of a magnetic recording medium and so forth and particularly relates to a Co—Cr—Pt-oxide-based sputtering target capable of improving discharge stability during sputtering.

### BACKGROUND ART

Various compositions are used in a sputtering target containing Co—Cr—Pt-oxide. For example, WO2013/136962 A1 (Patent Literature 1) discloses that a sputtering target based on Co—Cr—Pt-oxide contains, as its oxide, an oxide of one or more components selected from B, Si, Cr, Ti, Ta, W, Al, Mg, Mn, Ca, Zr, and Y and, as an additive element, one or more elements selected from B, Ti, V, Mn, Zr, Nb, Ru, Mo, Ta, W, Ag, Au, Cu, and C.

In such a sputtering target containing an oxide as an insulator, there was the problem of causing abnormal discharge and generating particles. To address this problem, the probability of abnormal discharge is commonly reduced by allowing the oxide to exist finely and uniformly in the texture of the sputtering target. For example, Patent Literature 1 also discloses that abnormal discharge can be suppressed by making the oxide fine to have an average particle size of 400 nm or less in the Co—Cr—Pt-oxide-based sputtering target.

WO2013/125469 A1 (Patent Literature 2) discloses that abnormal discharge and particle generation can effectively be suppressed by allowing oxide particles to exist in a spherical or near-spherical shape in addition to making such oxide particles fine since no difference arises in the distribution of oxide-existing regions and oxide-free regions in a certain area of a target surface, resulting in reduced segregation.

Meanwhile, many of sputtering targets having such a composition exhibit ferromagnetism and a low pass through flux (PTF) and thus require a high voltage to be applied during sputtering. A high voltage during sputtering arises the problem of making the voltage unstable and readily causing arcing. To this problem, a common solution is to lower a voltage required during sputtering by improving PTF. Several methods for improving PTF have been made public and, for example, Japanese Patent Laid-Open No. 2013-108110 (Patent Literature 3) describes a sputtering target comprising amagnetic phase and a non-magnetic phase interdispersed with an oxide phase, where the sputtering target comprises: a magnetic phase composed of a Co—Cr alloy phase containing 85 at % or more of Co; a non-magnetic phase composed of a Co—Cr alloy phase containing more than 0 at % and 75 at % or less of Co or composed of a Co—Cr—Pt alloy phase containing more than 0 at % and 73 at % or less of Co; and a non-magnetic phase composed of a Co—Pt alloy phase containing 12 at % or less of Co and thus controls the magnetism of each phase by the Co content to improve the PTF.

WO2011/089760 A1 (Patent Literature 4) discloses that the pass through flux is improved by having a metal matrix containing an inorganic material as well as a spherical (in particular, 30 to 150 μm in diameter) phase containing 90 wt % or more of Co.

Japanese Patent Laid-Open No. 2016-176087 (Patent Literature 5) discloses that a Co—Cr—Pt-oxide-based ferromagnetic sputtering target improves the pass through flux by having a metal matrix containing an inorganic material as well as a Pt phase of 10 to 150 μm in the shortest diameter. Moreover, WO2012/081669 A1 (Patent Literature 6) discloses that a Co—Cr—Pt-oxide-based ferromagnetic sputtering target improves the pass through flux and stabilizes a voltage during sputtering by having, in (A) an oxide-dispersed metal matrix, (B) a Co—Pt alloy phase of 10 to 150 μm in diameter and (C) a Co alloy phase of 30 to 150 μm in diameter containing 90 mol % or more of Co.

WO2010/110033 A1 (Patent Literature 7) discloses that a Co—Cr—Pt-oxide-based sputtering target improves the pass through flux by having (A) a phase in which non-magnetic particles are uniformly and finely dispersed in an alloy and (B) a spherical alloy phase having a composition of 25 mol % or more of Cr in the central part with decreasing Cr content from the central part toward the outer circumferential part as well as by setting the volume of the alloy phase (B) in the target to 4% or more and 40% or less.

### CITATION LIST

### Patent Literature

PTL 1: WO2013/136962 A1
PTL 2: WO2013/125469 A1
PTL 3: Japanese Patent Laid-Open No. 2013-108110
PTL 4: WO2011/089760 A1
PTL 5: Japanese Patent Laid-Open No. 2016-176087
PTL 6: WO2012/081669 A1
PTL 7: WO2010/110033 A1

### SUMMARY OF INVENTION

### Technical Problem

For Co—Cr—Pt-oxide-based sputtering targets, various compositions have been proposed.

WO2013/125469 A1 (Patent Literature 2) discloses suppressing abnormal discharge and reducing particles by making oxide particles have a predetermined shape, and Japanese Patent Laid-Open No. 2013-108110 (Patent Literature 3) discloses controlling the magnetism of each phase by varying the Co content in the magnetic phase and the non-magnetic phase improve the PTF, where the voltage stability is far from sufficient, however.

It is disclosed that the pass through flux is improved to stabilize a voltage during sputtering: by the presence of a spherical phase containing 90 wt % or more of Co in WO2011/089760 A1 (Patent Literature 4); by the presence of a Pt phase in Japanese Patent Laid-Open No. 2016-176087 (Patent Literature 5); by the presence of (B) a Co—Pt alloy phase and (C) a Co alloy phase containing 90 mol % or more of Co in the predetermined size and/or shape in WO2012/081669 A1 (Patent Literature 6); and by the presence of (B) a spherical alloy phase having a composition of 25 mol % or more of Cr in the central part with decreasing Cr content from the central part toward the outer circumferential part in WO2010/110033 A1 (Patent Literature 7). However, there is a problem that the composition and the pass through flux of a sputtering target used in the manufacture of magnetic recording media are limited to a composition and a pass through flux which exhibit magnetic properties necessary for such magnetic recording media and which are suitable for mass production and thus cannot be changed easily.

An object of the present invention is to provide a sputtering target capable of stabilizing a voltage during sputtering without taking measures of changing the composition or the pass through flux and to provide a manufacturing method therefor.

### Solution to Problem

The present inventors conducted intensive research for solving the above-mentioned problem and, as a result, found possible to lower a voltage during sputtering and stabilize discharge, while maintaining the composition and the pass through flux, by using a sputtering target having a texture containing 10/mm² or more of metal Cr phases of greater than 10 μm and 100 μm or less in equivalent circle diameter on the cross section of the sputtering target, thereby completing the present invention.

The present invention provides a Co—Cr—Pt-oxide-based sputtering target having the following features.
[1] A Co—Cr—Pt-oxide-based sputtering target containing 50 at % or more of Co, more than 0 at % and 20 at % or less of Cr, and more than 0 at % and 25 at % or less of Pt, with the balance being one or more oxides and incidental impurities, wherein the sputtering target contains
   (A) a composite phase in which Co, Pt, and one or more oxides are mutually dispersed and
   (B) a metal Cr phase; and
   wherein the sputtering target comprises 10 or more of metal Cr phases having an equivalent circle diameter of greater than 10 μm and 100 μm or less in a 1 mm×1 mm field of view under a SEM at a magnification of 50×.
[2] A Co—Cr—Pt-oxide-based sputtering target containing 50 at % or more of Co, more than 0 at % and 20 at % or less of Cr, and more than 0 at % and 25 at % or less of Pt, with the balance being one or more oxides and incidental impurities, wherein the sputtering target contains
   (A) a composite phase in which Co, Pt, and one or more oxides are mutually dispersed,
   (B) a metal Cr phase, and
   (C) an alloy phase containing Co or Pt; and
   wherein the sputtering target comprises 10 or more of metal Cr phases having an equivalent circle diameter of greater than 10 μm and 100 μm or less in a 1 mm×1 mm field of view under a SEM at a magnification of 50×.
[3] The sputtering target according to [1] or [2], wherein the composite phase further contains one or more selected from B, Al, Si, Ti, V, Mn, Fe, Ni, Cu, Zn, Ge, Nb, Mo, Ru, Rh, Pd, Ag, Ta, W, Re, Ir, and Au.
[4] The sputtering target according to any one of [1] to [3], wherein 20 vol % or more and 50 vol % or less of the oxides are contained in the sputtering target.
[5] The sputtering target according to any one of [1] to [4], wherein the oxides are each an oxide of one element or any combination of two or more elements selected from B, Mg, Al, Si, Ti, V, Cr, Mn, Fe, Co, Cu, Zn, Ga, Ge, Y, Zr, Nb, Mo, Ta, W, La, Ce, Nd, Sm, and Gd.
[6] The sputtering target according to any one of [1] to [5], wherein the oxides include at least boron oxide.
[7] A method for manufacturing the sputtering target according to [1] or [2], the method comprising:
   mixing/stirring a raw material powders including a Cr metal powder having an average particle size of 150 μm or more and 1000 μm or less and one or more oxide powders to prepare a mixed powder for a target; and
   sintering the mixed powder for a target.
[8] A method for manufacturing the sputtering target according to [1] or [2], the method comprising:
   adding a Cr metal powder having an average particle size of 10 μm or more and 150 μm or less to a mixed powder that has been obtained by stirring/mixing other raw material powders and one or more oxides.

### Advantageous Effects of Invention

A Co—Cr—Pt-oxide-based sputtering target of the present invention even with the same composition and pass through flux, due to the sputtering surface containing a metal Cr phase having an area of greater than 10 μm and 100 μm or less in equivalent circle diameter, is capable of lowering a voltage during sputtering, stabilizing discharge, and reducing the occurrence of arcing.

### BRIEF DESCRIPTION OF DRAWINGS

FIG. 1 is a diagram explaining the definition of equivalent circle diameter.

FIG. 2 is a texture image of the cross section of the sputtering target obtained in Example 1, in which the respective phases are identified by EDX mapping analysis.

FIG. 3 is a binarization processed image of an enlarged 1 mm×1 mm field of view from a SEM image that observes the cross section of the sputtering target obtained in Example 1 at a magnification of 50×.

FIG. 4 is a texture image of the cross section of the sputtering target obtained in Comparative Example 1, in which the respective phases are identified by EDX mapping analysis.

FIG. 5 is a texture image of the cross section of the sputtering target obtained in Comparative Example 2, in which the respective phases are identified by EDX mapping analysis.

FIG. 6 is a texture image of the cross section of the sputtering target obtained in Example 5, in which the respective phases are identified by EDX mapping analysis.

### DESCRIPTION OF EMBODIMENTS

Hereinafter, the present invention will be described in detail with reference to the appended drawings, but the present invention is not limited thereto.

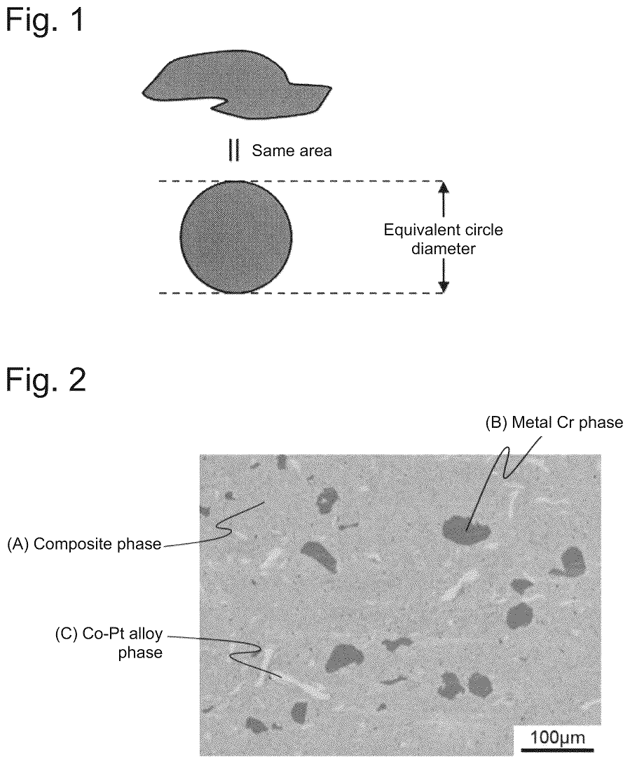

A Co—Cr—Pt-oxide-based sputtering target of the present invention is characterized by containing 10 or more metal Cr phases having an equivalent circle diameter of greater than 10 μm and 100 μm or less in a 1 mm×1 mm field of view under a SEM at a magnification of 50×. As shown in FIG. 1, the equivalent circle diameter means a diameter of a circle having an area comparable to an irregularly shaped metal Cr phase. As shown in the Examples described hereinafter, the presence of coarse metal Cr phases lowers a voltage during sputtering and stabilizes discharge. In the 1 mm×1 mm field of view under a SEM at a magnification of 50×, the metal Cr phases are dark or black in color, and the composite phase is light-colored, i.e., gray to white in color. The equivalent circle diameter can be calculated by binarization processing an observed SEM image to extract a dark-or black-colored metal Cr phase and determine the area thereof.

The metal Cr phase can be identified by EDX mapping analysis of the cross section of a sputtering target. When quantitatively analyzing the weight ratio of a target composition, a region of 100 wt % of Cr ideally is a “metal Cr phase”, but a region composed of 95 wt % or more and preferably 97 wt % or more of Cr and incidental impurities is also regarded as a “metal Cr phase” in view of inevitable analytical errors.

### First Embodiment

A Co—Cr—Pt-oxide-based sputtering target of the first embodiment is a Co—Cr—Pt-oxide-based sputtering target containing 50 at % or more of Co, more than 0 at % and 20 at % or less of Cr, and more than 0 at % and 25 at % or less of Pt, with the balance being one or more oxides and incidental impurities, characterized by containing
(A) a composite phase in which Co, Pt, and one or more oxides are mutually dispersed and
(B) a metal Cr phase; and
wherein the sputtering target comprises 10 or more of metal Cr phases having an equivalent circle diameter of greater than 10 μm and 100 μm or less in a 1 mm×1 mm field of view under a SEM at a magnification of 50×.

The metal Cr phase (B) has an equivalent circle diameter of greater than 10 μm and 100 μm or less, preferably an equivalent circle diameter of 20 μm or more, more preferably 25 μm or more and preferably an equivalent circle diameter of 70 μm or less, more preferably 60 μm or less. When the metal Cr phase has an equivalent circle diameter exceeding 100 μm, significant unevenness appears on a target surface during sputtering due to differences in sputtering rate, thereby readily causing problems, such as particles and arcing. Meanwhile, when the metal Cr phase has an equivalent circle diameter of 10 μm or less, the voltage lowering effect during sputtering becomes difficult to attain, and a Cr alloy phase or a Cr oxide phase tends to form due to readily proceeding diffusion reactions with other phases at the grain boundaries of the metal Cr phase.

In a 1 mm×1 mm field of view under a SEM at a magnification of 50×, there exist 10 or more, preferably 15 or more, more preferably 20 or more and preferably 300 or fewer, more preferably 100 or fewer of metal Cr phases having an area within the above-described ranges. When fewer than 10 metal Cr phases exist, it is impossible to attain sufficiently the voltage lowering effect during sputtering. When the presence of 10 or more of metal Cr phases can be confirmed in a 1 mm×1 mm field of view, it can be said that the metal Cr phases are uniformly dispersed throughout the sputtering target. When more than 300 of metal Cr phases exist, considerable unevenness appears on a target surface during sputtering due to differences in sputtering rate, thereby readily causing problems, such as particles and arcing. Note that incomplete metal Cr phases appearing at the edges of the field of view are not counted.

In a sputtered thin film, Co plays a central role in the formation of magnetic particles of a granular structure. In the Co—Cr—Pt-oxide-based sputtering target of the present invention, the Co content based on the entire target is 50 at % or more, preferably 55 at % or more, more preferably 60 at % or more and preferably 90 at % or less, more preferably 80 at % or less and falls within the content range required as a recording layer of a magnetic recording medium.

In the Co—Cr—Pt-oxide-based sputtering target of the present invention, the Pt content based on the entire target is more than 0 at % and 25 at % or less, preferably 5 at % or more, more preferably 10 at % or more and preferably 23 at % or less, more preferably 22 at % or less and falls within the content range required as a recording layer of a magnetic recording medium. In a sputtered thin film, Pt acts to increase the magnetic moment of Co through alloying with Co, which is a magnetic particle of a granular structure, and thus has a role of adjusting the magnetic strength of the magnetic particles.

In the Co—Cr—Pt-oxide-based sputtering target of the present invention, the Cr content based on the entire target is more than 0 at % and 20 at % or less, preferably 1 at % or more, more preferably 3 at % or more and preferably 15 at % or less, more preferably 10 at % or less and falls within the content range required as a recording layer of a magnetic recording medium. In a sputtered thin film, Cr acts to decrease the magnetic moment of Co through alloying with Co, which is a magnetic particle of a granular structure, and thus has a role of adjusting the magnetic strength of the magnetic particles.

In a sputtered thin film, an oxide acts as a partition wall that isolates each alloy phase to form a granular structure. In the Co—Cr—Pt-oxide-based sputtering target of the present invention, the oxide content based on the entire target is desirably 20 vol % or more and 50 vol % or less, preferably 25 vol % or more, more preferably 30 vol % or more and 45 vol % or less, more preferably 40 vol % or less and falls within the content range required as a recording layer of a magnetic recording medium.

The Co—Cr—Pt-oxide-based sputtering target of the present invention contains (A) a composite phase in which Co, Pt, and one or more oxides are mutually dispersed, and (B) a metal Cr phase. In the composite phase (A), metals (Co, Cr, Pt, and so forth) or an alloy and one or more oxides are mutually uniformly dispersed, where oxides having high electrical resistance are desirably dispersed finely in view of voltage stability. The metal Cr phase (B), which are non-magnetic materials, can maintain the magnetic properties even when separated from the composite phase (A) and, although the clear reason is unknown, can lower a voltage during sputtering, stabilize discharge, and reduce the occurrence of arcing.

The oxides contained in the composite phase (A) are each preferably an oxide of one element or any combination of two or more elements selected from B, Mg, Al, Si, Ti, V, Cr, Mn, Fe, Co, Cu, Zn, Ga, Ge, Y, Zr, Nb, Mo, Ta, W, La, Ce, Nd, Sm, and Gd and preferably include at least boron oxide. Preferable examples of the oxides include B₂O₃, SiO₂, Co₃O₄, Cr₂O₃, CoO, TiO₂, Ta₂O₅, MnO, Mn₂O₃, Nb₂O₅, ZnO, WO₃, VO₂, MgO, ZrO₂, Al₂O₃, and Y₂O₃.

The composite phase (A) can further contain one or more selected from B, Al, Si, Ti, V, Mn, Fe, Ni, Cu, Zn, Ge, Nb, Mo, Ru, Rh, Pd, Ag, Ta, W, Re, Ir, and Au. These additive elements are preferably contained as an alloy with Co and Pt. In a thin film formed by sputtering, these additive elements have a role of adjusting the magnetic strength of magnetic particles through alloying with Co, which is a magnetic particle of a granular structure. In particular, Ru and B are effective in adjusting the magnetic moment of Co.

### Second Embodiment

A Co—Cr—Pt-oxide-based sputtering target of the second embodiment is a Co—Cr—Pt-oxide-based sputtering target containing 50 at % or more of Co, more than 0 at % and 20 at % or less of Cr, and more than 0 at % and 25 at % or less of Pt, with the balane being one or more oxides and incidental impurities, characterized by containing
(A) a composite phase in which Co, Pt, and one or more oxides are mutually dispersed,
(B) a metal Cr phase, and
(C) an alloy phase containing Co or Pt; and
wherein the sputtering target comprises 10 or more metal Cr phases having an equivalent circle diameter of greater than 10 μm and 100 μm or less in a 1 mm×1 mm field of view under a SEM at a magnification of 50×.

The sputtering target of the second embodiment is the same as the first embodiment except for further comprising (C) the alloy phase containing Co or Pt, and hence, explanations the same as the first embodiment will be omitted.

By including (C) the alloy phase containing Co or Pt, the second embodiment can lower the melting point in many cases as compared with the highest melting point among metal Co, metal Pt, and any other components of the alloy, can improve sinterability due to such a lowered melting point of the raw material powders, and as a result, can effectively lower the sintering temperature. Accordingly, a denser sintered body can be obtained when sintered at the same temperature as the sintering temperature in the case of containing no alloy phase, and on the other hand, manufacturing costs are also effectively reduced by lowering the sintering temperature while maintaining the high density.

The alloy phase (C) is an alloy phase containing Co or Pt as a main component and does not contain any oxide. The alloy phase can be one or any combination of two or more selected from: a Co alloy phase containing 50 at % or more, preferably 30 at % or more, and more preferably 10 at % or more of Co; a Pt alloy phase containing 50 at % or more, preferably 30 at % or more, and more preferably 10 at % or more of Pt; a Co—Pt alloy phase containing 50 at % or more of Co and 50 at % or less of Pt; and a Co—Pt alloy phase containing 50 at % or less of Co and 50 at % or more of Pt. The Co alloy phase or the Pt alloy phase can contain B, Cr, Si, Ti, Ru, Mn, Nb, Zn, W, V, and/or Ta as other components.

The sputtering target of the present invention can be manufactured by stirring/mixing a Cr metal powder having an average particle size of 150 μm or more and 1000 μm or less, other raw material powders, and one or more oxides to prepare a mixed powder for a target, and sintering the mixed powder for a target. Alternatively, the sputtering target can be manufactured by stirring/mixing other raw material powders and one or more oxide powders, then, adding thereto a Cr metal powder having an average particle size of 10 μm or more and 150 μm or less, preferably 20 μm or more, more preferably 25 μm or more and preferably 100 μm or less, more preferably 50 μm or less, further stirring/mixing to prepare a mixed powder for a target, and sintering the mixed powder for a target. Note that the metal Cr phase in the sputtering target mostly has, through the stirring/mixing process, a size comparable to or smaller than the Cr metal powder loaded, however, metal Cr phases larger than the particle size of the Cr metal powder loaded exist in some cases through diffusion bonding of the Cr metal powder in the process, such as sintering during the manufacture of a target.

An alloy powder may be produced by a gas atomization process. A suitably used alloy powder may be, for example, Co—Pt alloy, Co—B alloy, Pt—B alloy, Co—Cr—Pt alloy, Co—Ru alloy, Co—Cr—Ru alloy, Co—Si alloy, Co—Cr alloy, Co—Cr—Pt—B alloy, Co—Cr—Pt—Ru alloy, or Co—Cr—Pt—Ru—B alloy.

Next, a mixed powder is obtained by loading weighed raw material powders into a stirring/pulverizing apparatus, such as a ball mill, and uniformly mixing and dispersing the raw material powders through stirring/mixing. The stirring/mixing conditions can suitably be adjusted to attain uniform mixing and dispersing of the raw material powders. For example, when the particle sizes of the raw material powders are close to the intended texture, pulverization is suppressed preferably. In such a case, a stirrer or a tumbling mixer can be used without using grinding media, or when pulverization is required, a mixing apparatus using grinding media, such as a ball mill, can be used. Moreover, in order to form a metal Cr phase having an equivalent circle diameter of greater than 10 μm and 100 μm or less, it is preferable to divide the stirring/mixing step into two or more stages, load later a metal Cr powder having an average particle size of 10 μm or more and 150 μm or less, and stir gently. Further, when the Cr content is high in the designed composition of a sputtering target, it is possible to divide the loading step of a metal Cr powder into two or more stages and adjust the number of coarse metal Cr phases present in the sputtering target.

Subsequently, a sintered body is obtained by sintering the mixed powder for a sputtering target. As for the sintering conditions, a known sintering process, such as hot pressing, spark plasma sintering (SPS), or hot isostatic pressing (HIP), may be used as long as a high-density sintered body having a relative density of 90% or more can be obtained. The sintering temperature varies depending on the composition and the properties of the mixed powder but is generally about 600° C. or higher and 1200° C. or lower for a Co—Cr—Pt-oxide-based sputtering target. It is also possible to raise a temperature while observing the displacement in the pressing direction during sintering and set a temperature at which the displacement stabilizes as the sintering temperature.

### EXAMPLES

### Production of Sputtering Targets

### Example 1

To satisfy the designed composition for the sputtering target of Example 1 shown in Table 1: 63 at % Co—6 at % Cr—22 at % Pt—2 at % SiO₂—1 at % Co₃O₄—6 at % B₂O₃, a 50 Co—50 Pt alloy powder (abbreviated as “Co—50 Pt alloy powder” in some cases), a Co powder, a Cr powder, a SiO₂ powder, a Co₃O₄ powder, and a B₂O₃ powder were weighed respectively. As the Co-50 Pt alloy powder and the Co powder, powders manufactured by gas atomization were used. As the Co-50 Pt alloy powder and the Co powder, powders that had passed through a sieve of 106 μm openings were used. As the Cr powder, a powder that had passed through a sieve of 45 μm openings and that had an average particle size of 35 μm was used.

The weighed powders excluding the Cr powder were loaded into a ball mill pot and subjected to the first stirring/mixing until sufficiently finely and mutually dispersed. Thereafter, the Cr powder was loaded into the ball mill pot and subjected to the second stirring/mixing to give a mixed powder for sintering. The second stirring/mixing was controlled, by lowering the input energy as compared with the first stirring/mixing, such that Cr phases did not become finer. Specifically, the total number of revolutions in the second stirring/mixing was set to 1/140 of the first stirring/mixing. As for the stirring/mixing in Examples 2 to 25 described hereinafter as well, the total number of revolutions in the second stirring/mixing was set to 1/70 or less of the first stirring/mixing.

A sintered body was obtained by filling a carbon die with the resulting mixed powder and hot pressing. The sintering conditions were set to a sintering temperature of 750° C. and a retention time of 1 hour in a vacuum atmosphere. Here, in order to attain high density as 95% or more relative density, the temperature was raised while observing the displacement in the pressing direction during sintering, and a temperature at which the displacement stabilizes was set as the sintering temperature. The relative density of the resulting sintered body was measured by the Archimedes method to confirm that a high-density sintered body having a relative density of 99% was obtained. The sintered body was subjected to finish machining to produce a sputtering target having a diameter of 165 mm and a thickness of 6.4 mm. As for Examples 2 to 25 and Comparative Examples 1 to 19 described hereinafter as well, the sintering temperature was determined in the same manner to be 650° C. to 1200° C.

### Example 2

In Example 2, a sputtering target was produced in the same manner as Example 1 except for increasing the input energy during the second stirring/mixing.

### Example 3

In Example 3, a sputtering target was produced in the same manner as Example 1 except for increasing the input energy during the second stirring/mixing as compared with Example 2.

### Example 4

A sputtering target was produced using, as a Cr powder among the raw material powders, a large powder that had passed through a sieve of 1000 μm openings but not a sieve of 150 μm openings by loading all the raw material powders together into a ball mill pot, stirring/mixing simultaneously to give a mixed powder, and sintering the resulting mixed powder in the same manner as Example 1.

### Comparative Example 1

A sputtering target was produced by loading all the raw material powders the same as Example 1 together into a ball mill pot, stirring/mixing simultaneously to give a mixed powder, and sintering the resulting mixed powder in the same manner as Example 1.

### Example 5

A sputtering target was produced in the same manner as Example 1 except for using, in place of the Co-50 Pt alloy powder among the raw material powders, a Pt powder that had passed through a sieve of 106 μm openings.

### Comparative Example 2

A sputtering target was produced in the same manner as Comparative Example 1 except for using, in place of the Co-50 Pt alloy powder among the raw material powders, a Pt powder that passed through a sieve of 106 μm openings.

### Examples 6 to 25

Each sputtering target was produced in the same manner as Example 1 by weighing the respective raw material powders to satisfy the sputtering target designed composition shown for Examples 6 to 25 in Table 1. In Examples 9 and 15, a Pt powder that had passed through a sieve of 106 μm openings was used in place of the Co-50 Pt alloy powder. In Example 17, a Co-18.5 B alloy powder was used in place of the B powder. In Example 24, a Co-90 Pt alloy powder was used in place of the Co-50 Pt alloy powder. In Example 25, a Co-10 Pt alloy powder was used in place of the Co-50 Pt alloy powder.

### Comparative Examples 3 to 22

Each sputtering target was produced in the same manner as Comparative Example 1 by weighing the respective raw material powders to satisfy the sputtering target designed composition shown for Comparative Examples 3 to 22 in Table 1. In Comparative Examples 6 and 12, a Pt powder that had passed through a sieve of 106 μm openings was used in place of the Co-50 Pt alloy powder. In Comparative Example 14, a Co-18.5 B alloy powder was used in place of the B powder. In Comparative Example 21, a Co-90 Pt alloy powder was used in place of the Co-50 Pt alloy powder. In Comparative Example 22, a Co-10 Pt alloy powder was used in place of the Co-50 Pt alloy powder.

### Texture Analysis

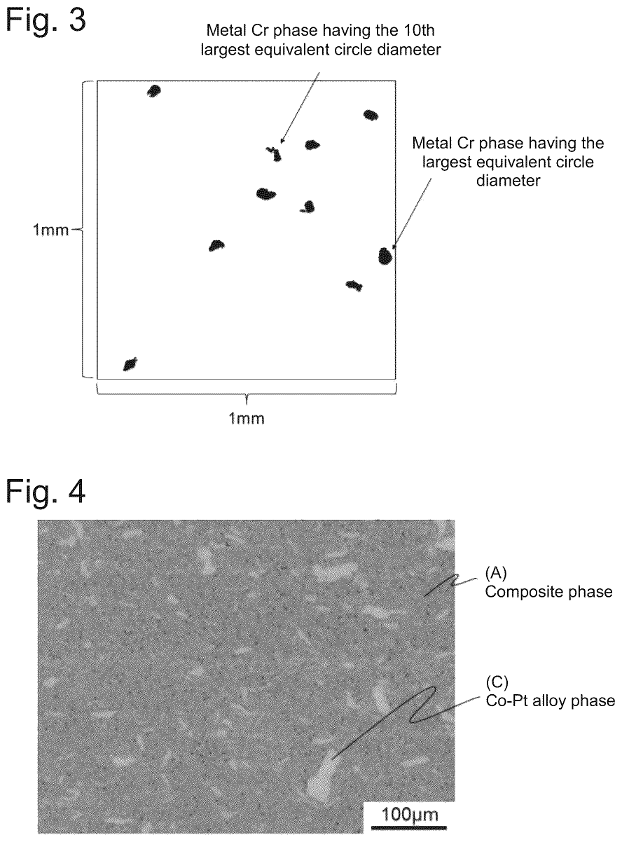

A test piece for texture observation was cut out from the resulting sputtering target and subjected to, after mirror polishing of the cross section of the test piece, EDX mapping analysis of main components in each phase contained. The results of Example 1 are shown in FIG. 2. It was confirmed that the cross section of the sputtering target was composed of a composite phase in which metals and oxides are finely dispersed (matrix of gray in color in FIG. 2), a Co—Pt alloy phase (phase of white in color in FIG. 2), and a metal Cr phase (phase of black in color in FIG. 2). As for the metal Cr phase, it was confirmed, through quantitative analysis of the weight ratio of the target composition, that each phase for which only Cr had been mainly detected by compositional mapping was composed of Cr and incidental impurities. Subsequently, an image in the range of a 1 mm×1 mm field of view at a magnification of 50× was obtained by a SEM and subjected, using image analysis software, to binarization processing into the metal Cr phase of black in color and other phases of white in color and further to extraction of only the metal Cr phases having the largest to the tenth largest equivalent circle diameters to determine equivalent circle diameters for the largest metal Cr phase and the tenth largest metal Cr phase. An image for Example 1 is shown in FIG. 3. In FIG. 3 showing the results of Example 1, the equivalent circle diameter of the tenth largest metal Cr phase was 37 μm, and the equivalent circle diameter of the largest metal Cr phase was 50 μm. The measurement was impossible when the number of detectable metal Cr phases was less than ten: this is denoted as “−” in Table 1.

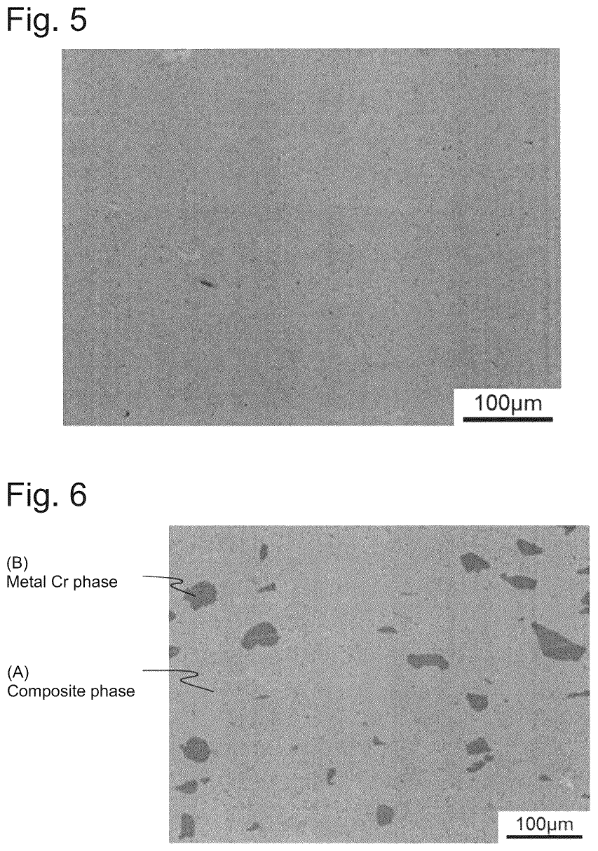

As a result of the texture observation of the cross section of sputtering targets, no metal Cr phase having an equivalent circle diameter of greater than 10 μm and 100 μm or less was detected in Comparative Examples 1 to 22. As the representative examples, a texture image for the cross section of the sputtering target of Comparative Example 1 is shown in FIG. 4, and a texture image for the cross section of the sputtering target of Comparative Example 2 is shown in FIG. 5.

In Examples 5, 9, and 15, only (A) a composite phase composed of Co, Pt and oxides and (B) metal Cr phases, but not any Co—Pt alloy phase, were detected, where the equivalent circle diameter of the tenth largest metal Cr phase exceeded 10 μm and the equivalent circle diameter of the largest metal Cr phase was 100 μm or less. As the representative example, a texture image for the cross section of the target of Example 5 is shown in FIG. 6.

In Examples 1 to 4, 6 to 8, 10 to 14 and 16 to 25, (A) a composite phase composed of Co, Pt and oxides, (B) metal Cr phases, and (C) Co—Pt alloy phases were detected, where the equivalent circle diameter of the tenth largest metal Cr phase exceeded 10 μm and the equivalent circle diameter of the largest metal Cr phase was 100 μm or less.

### Pass Through Flux

For the resulting sputtering targets, the pass through flux (PTF) was measured in accordance with ASTM F2086-01. The pass through flux is evaluated as satisfactory and denoted as “Good” in Table 1 when the pass through flux can be maintained within less than 2% lowering of or exceeds a control pass through flux measured for a sputtering target (Comparative Example) having the same composition but containing no metal Cr phase. In Examples 1 to 25, it was confirmed that the PTF was comparable to or higher than that of the corresponding Comparative Example having the same composition.

### Sputtering Discharge Voltage

A sputtering discharge voltage was measured using a data logger, after mounting the resulting sputtering target on a magnetron sputtering apparatus, while allowing argon gas to flow at argon gas pressure of 1.0 Pa and continuing sputtering discharge at an input power of 1000 W. The data logger was set to repeat 100 times the measurement of 15,000 points data in a sampling period of 2 microseconds. A sputtering discharge voltage value under these measurement settings was calculated by averaging the 15,000 points data of each measurement and further averaging such calculated average values of the 100 measurements. Discharge stability is considered to be improved when a sputtering discharge voltage can be lowered by 20 V or more as compared with that of a sputtering target (Comparative Example) having the same composition but containing no metal Cr phase. In Examples 1 to 25, it was confirmed that the discharge voltage is lowered by 20 V or more as compared with the corresponding Comparative Example having the same composition.

### Relative Density

In all the Examples and Comparative Examples, the relative density of each sputtering target was 95% or more.

TABLE 1
Measurement Results of Examples and Comparative Examples

| | | | | Equivalent | Equivalent | | | | |
|---|---|---|---|---|---|---|---|---|---|
| | | | | circle | circle | | | | |
| | | | | diameter | diameter | | PTF | Voltage | Discharge |
| | | | | of 10th | of largest | | main- | value at | voltage |
| | | B₂O₃ | Oxide | Cr phase | Cr phase | Alloy | taining | 1000 W | difference |
| | Designed composition of sputtering target | (vol. %) | (vol. %) | (μm) | (μm) | phase | effect | (V) | (V) |
| Example 1 | 63Co—6Cr—22Pt—2SiO₂—1Co₃O [symbol] —6B₂O₃ | 23.1 | 32.7 | 37 | 50 | [symbol] | Good | [symbol] | [symbol] |
| Example 2 | | | | 24 | [symbol] | [symbol] | Good | [symbol] | [symbol] |
| Example 3 | | | | [symbol] | [symbol] | [symbol] | Good | 495 | 22 |
| Example 4 | | | | 11 | 17 | [symbol] | Good | [symbol] | 24 |
| Comp. | | | | — | — | [symbol] | Control | 517 | — |
| Ex 1 | | | | | | | | | |
| Example 5 | | | | [symbol] | [symbol] | None | Good | [symbol] | [symbol] |
| Comp. | | | | — | — | None | Control | [symbol] | |
| Ex 2 | | | | | | | | | |
| Example 6 | 63Co—4Cr—21Pt—3SiO2—5Cr₂O₃—4B [symbol] O [symbol] | 14.9 | 37.3 | 45 | 53 | [symbol] | Good | 470 | 52 |
| Comp. | | | | — | — | [symbol] | Control | [symbol] | |
| Ex 3 | | | | | | | | | |
| Example 7 | 73.5Co—0.5Cr—20Pt—2SiO₂—1CoO—3B₂O [symbol] | [symbol] | 21.1 | 14 | 25 | [symbol] | Good | 401 | [symbol] |
| Comp. | | | | — | — | [symbol] | Control | 432 | |
| Ex 4 | | | | | | | | | |
| Example 8 | 60Co—2Cr—25Pt—3SiO₂—3TiO2—3Co₃O₄—4B₂O₃ | 14.4 | 39.0 | 29 | [symbol] | [symbol] | Good | [symbol] | [symbol] |
| Comp. | | | | — | — | [symbol] | Control | 503 | |
| Ex 5 | | | | | | | | | |
| Example 9 | 60Co—4Cr—19Pt—3TiO2—4Co [symbol] O₄—1 [symbol] B₂O [symbol] | [symbol] | 49.8 | [symbol] | [symbol] | None | Good | [symbol] | [symbol] |
| Comp. | | | | — | — | None | Control | [symbol] | |
| Ex 6 | | | | | | | | | |
| Example 10 | 67Co—3Cr—23Pt—7B₂O₃ | 28.2 | 28.2 | [symbol] | 43 | [symbol] | Good | 418 | [symbol] |
| Comp. | | | | — | — | [symbol] | Control | 453 | |
| Ex 7 | | | | | | | | | |
| Example 11 | 65Co—5Cr—15Pt—15B₂O₃ | 48.5 | 48.5 | [symbol] | | [symbol] | Good | [symbol] | [symbol] |
| Comp. | | | | — | — | [symbol] | Control | 571 | |
| Ex 8 | | | | | | | | | |
| Example 12 | 62Co—15Cr—11Pt—4Ru—2B—4SiO₂—2B₂O₃ | [symbol] | 21.8 | 48 | 61 | [symbol] | Good | [symbol] | 25 |
| Comp. | | | | — | — | [symbol] | Control | 422 | |
| Ex 9 | | | | | | | | | |
| Example 13 | 68Co—5Cr—18Pt—3TiO₂—3B₂O [symbol] —3Ta₃O₅ | 11.6 | [symbol] | [symbol] | 47 | [symbol] | Good | 451 | 41 |
| Comp. | | | | — | — | [symbol] | Control | [symbol] | |
| Ex 10 | | | | | | | | | |
| Example 14 | 67Co—3Cr—21Pt—2SiO [symbol] —6B [symbol] O₃—1MnO | [symbol] | 31.0 | 31 | 43 | [symbol] | Good | [symbol] | [symbol] |
| Comp. | | | | — | — | [symbol] | Control | 506 | |
| Ex 11 | | | | | | | | | |
| Example 15 | 69Co—5Cr— [symbol] 6Pt— [symbol] CoO—6B₂O [symbol] —3Mn₂O₃ | 23.1 | [symbol] | 33 | 47 | None | Good | [symbol] | [symbol] |
| Comp. | | | | — | — | None | Control | [symbol] | |
| Ex 12 | | | | | | | | | |
| Example 16 | 61Co—4Cr—20Pt—11CoO—4B [symbol] O [symbol] | [symbol] | 31.2 | 33 | 43 | [symbol] | Good | 421 | 22 |
| Comp. | | | | — | — | [symbol] | Control | 443 | |
| Ex 13 | | | | | | | | | |
| Example 17 | 72Co—4Cr—14Pt—2B—2Co [symbol] O [symbol] —6B₂O [symbol] | 23.9 | 32.3 | [symbol] | 45 | [symbol] | Good | 427 | 35 |
| Comp. | | | | — | — | [symbol] | Control | [symbol] | |
| Ex 14 | | | | | | | | | |
| Example 18 | 75Co—7Cr—10Pt—7SiO₂—1B [symbol] O [symbol] | [symbol] | [symbol] | 43 | 5 | [symbol] | Good | [symbol] | 40 |
| Comp. | | | | — | — | [symbol] | Control | 429 | |
| Ex 15 | | | | | | | | | |
| Example 19 | 6 [symbol] Co—7Cr—13Pt—2Ru—3TiO [symbol] —1Cr₂O [symbol] —5B₂O₃ | [symbol] | [symbol] | [symbol] | 80 | [symbol] | Good | 391 | [symbol] |
| Comp. | | | | — | — | [symbol] | Control | [symbol] | |
| Ex 16 | | | | | | | | | |
| Example 20 | 57Co—4Cr—20Pt—5SiO₂—5TiO₂—9CoP | 0.0 | 36.3 | [symbol] | 48 | [symbol] | Good | 428 | [symbol] |
| Comp. | | | | — | — | [symbol] | Control | 465 | |
| Ex 17 | | | | | | | | | |
| Example 21 | 56Co— [symbol] Cr—13Pt—2Ru—11B—3TiO₂—5Co [symbol] O [symbol] | 0.0 | [symbol] | [symbol] | | [symbol] | Good | [symbol] | [symbol] |
| Comp. | | | | — | — | [symbol] | Control | [symbol] | |
| Ex 18 | | | | | | | | | |
| Example 22 | 6 [symbol] Co—5Cr—20Pt—3Co [symbol] O4—4B [symbol] O [symbol] —2Nb [symbol] O [symbol] | 14.5 | 37.3 | 40 | 53 | [symbol] | Good | 451 | [symbol] |
| Comp. | | | | — | — | [symbol] | Control | [symbol] | |
| Ex 19 | | | | | | | | | |
| Example 23 | 69Co—1Cr—20Pt—2SiO2—1CoO—5B [symbol] O [symbol] —2ZnO | [symbol] | [symbol] | 15 | 22 | [symbol] | Good | [symbol] | [symbol] |
| Comp. | | | | — | — | [symbol] | Control | 441 | |
| Ex 20 | | | | | | | | | |
| Example 24 | 63Co—5Cr—22Pt—2Cr₂O [symbol] —5B [symbol] O [symbol] —3WO₃ | [symbol] | 34.5 | 36 | 80 | [symbol] | Good | [symbol] | 41 |
| Comp. | | | | — | — | [symbol] | Control | 504 | |
| Ex 21 | | | | | | | | | |
| Example 25 | 5 [symbol] Co— [symbol] Cr—13Pt—2Co3O [symbol] —4 [symbol] O—2Vo₂ | [symbol] | 29.2 | [symbol] | 71 | [symbol] | Good | [symbol] | [symbol] |
| Comp. | | | | — | — | [symbol] | Control | 433 | |
| Ex 22 | | | | | | | | | |

[symbol]

indicates data missing or illegible when filed

1. A Co—Cr—Pt-oxide-based sputtering target comprising 50 at % or more of Co, more than 0 at % and 20 at % or less of Cr, and more than 0 at % and 25 at % or less of Pt, with the balance being one or more oxides and incidental impurities, wherein the sputtering target comprises
(A) a composite phase in which Co, Pt, and one or more oxides are mutually dispersed and
(B) a metal Cr phase; and
wherein the sputtering target comprises 10 or more metal Cr phases having an equivalent circle diameter of greater than 10 μm and 100 μm or less in a 1 mm×1 mm field of view under a SEM at a magnification of 50×.

2. A Co—Cr—Pt-oxide-based sputtering target comprising 50 at % or more of Co, more than 0 at % and 20 at % or less of Cr, and more than 0 at % and 25 at % or less of Pt, with the balance being one or more oxides and incidental impurities, wherein the sputtering target comprises
(A) a composite phase in which Co, Pt, and one or more oxides are mutually dispersed,
(B) a metal Cr phase, and
(C) an alloy phase containing Co or Pt; and
wherein the sputtering target comprises 10 or more metal Cr phases having an equivalent circle diameter of greater than 10 μm and 100 μm or less in a 1 mm×1 mm field of view under a SEM at a magnification of 50×.

3. The sputtering target according to claim 1, wherein the composite phase further comprises one or more selected from B, Al, Si, Ti, V, Mn, Fe, Ni, Cu, Zn, Ge, Nb, Mo, Ru, Rh, Pd, Ag, Ta, W, Re, Ir, and Au.

4. The sputtering target according to claim 1, wherein 20 vol % or more and 50 vol % or less of the oxides are contained in the sputtering target.

5. The sputtering target according to claim 1, wherein the oxides are each an oxide of one element or any combination of two or more elements selected from B, Mg, Al, Si, Ti, V, Cr, Mn, Fe, Co, Cu, Zn, Ga, Ge, Y, Zr, Nb, Mo, Ta, W, La, Ce, Nd, Sm, and Gd.

6. The sputtering target according to claim 1, wherein the oxides include at least boron oxide.

7. The sputtering target according to claim 1, wherein:
the composite phase further comprises one or more selected from B, Al, Si, Ti, V, Mn, Fe, Ni, Cu, Zn, Ge, Nb, Mo, Ru, Rh, Pd, Ag, Ta, W, Re, Ir, and Au; and
the oxides include at least boron oxide and further an oxide of one element or any combination of two or more elements selected from Mg, Al, Si, Ti, V, Cr, Mn, Fe, Co, Cu, Zn, Ga, Ge, Y, Zr, Nb, Mo, Ta, W, La, Ce, Nd, Sm, and Gd.

8. A method for manufacturing the sputtering target according to claim 1, comprising:
mixing/stirring raw material powders including a Cr metal powder having an average particle size of 150 μm or more and 1000 μm or less and one or more oxide powders to prepare a mixed powder for a target; and
sintering the mixed powder for a target.

9. A method for manufacturing the sputtering target according to claim 1, comprising:
adding a Cr metal powder having an average particle size of 10 μm or more and 150 μm or less to a mixed powder that has been obtained by mixing/stirring other raw material powders and one or more oxide powders in advance, thereby preparing a mixed powder for a target; and
sintering the mixed powder for a target.

10. The sputtering target according to claim 2, wherein the composite phase further comprises one or more selected from B, Al, Si, Ti, V, Mn, Fe, Ni, Cu, Zn, Ge, Nb, Mo, Ru, Rh, Pd, Ag, Ta, W, Re, Ir, and Au.

11. The sputtering target according to claim 2, wherein 20 vol % or more and 50 vol % or less of the oxides are contained in the sputtering target.

12. The sputtering target according to claim 2, wherein the oxides are each an oxide of one element or any combination of two or more elements selected from B, Mg, Al, Si, Ti, V, Cr, Mn, Fe, Co, Cu, Zn, Ga, Ge, Y, Zr, Nb, Mo, Ta, W, La, Ce, Nd, Sm, and Gd.

13. The sputtering target according to claim 2, wherein the oxides include at least boron oxide.

14. The sputtering target according to claim 2, wherein:
the composite phase further comprises one or more selected from B, Al, Si, Ti, V, Mn, Fe, Ni, Cu, Zn, Ge, Nb, Mo, Ru, Rh, Pd, Ag, Ta, W, Re, Ir, and Au; and
the oxides include at least boron oxide and further an oxide of one element or any combination of two or more elements selected from Mg, Al, Si, Ti, V, Cr, Mn, Fe, Co, Cu, Zn, Ga, Ge, Y, Zr, Nb, Mo, Ta, W, La, Ce, Nd, Sm, and Gd.

15. A method for manufacturing the sputtering target according to claim 2, comprising:
mixing/stirring raw material powders including a Cr metal powder having an average particle size of 150 μm or more and 1000 μm or less and one or more oxide powders to prepare a mixed powder for a target; and
sintering the mixed powder for a target.

16. A method for manufacturing the sputtering target according to claim 2, comprising:
adding a Cr metal powder having an average particle size of 10 μm or more and 150 μm or less to a mixed powder that has been obtained by mixing/stirring other raw material powders and one or more oxide powders in advance, thereby preparing a mixed powder for a target; and
sintering the mixed powder for a target.
